(19) United States
(12) Patent Application Publication
(10) Pub. No.: US 2022/0291584 A1
(43) Pub. Date: Sep. 15, 2022

(54) Resin Composition, Method for Manufacturing Cured Product, Cured Product, Patterned Cured Product, Interlayer Insulation Film, Cover Coating Layer, Surface Protection Film, and Electronic Component

(71) Applicant: HD Microsystems, Ltd., Tokyo (JP)

(72) Inventors: Ayaka AZUMA, Tokyo (JP); Satoshi ABE, Tokyo (JP); Kazuya SOEJIMA, Tokyo (JP)

(21) Appl. No.: 17/633,383

(22) PCT Filed: Aug. 8, 2019
(86) PCT No.: PCT/JP2019/031420

§ 371 Date: Feb. 7, 2022

(51) Int. Cl. G03F 7/039; C08K 5/41; C08K 5/20; C08K 5/3475; C08K 5/3472; C08K 5/544

(52) U.S. Cl. CPC G03F 7/039; C08K 5/41; C08K 5/20; C08K 5/3475; C08K 5/3472; C08K 5/544; H01L 23/5329

(57) ABSTRACT

A resin composition comprising the following component (A), the following component (B), and one or more selected from the group consisting of the following component (C) and the following component (D).

(A) polyimide, a polyimide precursor, polybenzoxazole, or a polybenzoxazole precursor
(B) one or more selected from the group consisting of a compound represented by the following formula (11), a compound represented by the following formula (21), and N-methyl-2-pyrrolidone
(C) a rust inhibitor
(D) a silane coupling agent

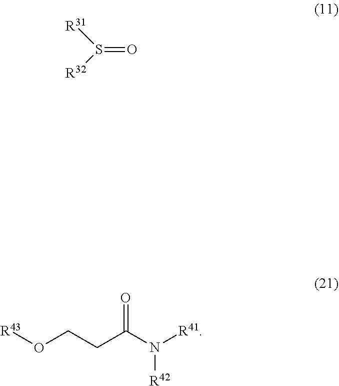

### TECHNICAL FIELD

The invention relates to a resin composition, a method of production of a cured product, a cured product, a patterned cured product, an interlayer insulating film, a cover coat layer, a surface protective film, and an electronic component.

### BACKGROUND ART

Heretofore, polyimide and polybenzoxazole having excellent heat resistance, electrical characteristics, mechanical characteristics, and the like at the same time have been used fora surface protective film and an interlayer insulating film of a semiconductor element. In recent years, photosensitive resin compositions which are imparted photosensitive characteristics to themselves are used, and by using such photosensitive resin compositions, the production process of a patterned cured product can be simplified, and complicated production processes can be shortened (for example, see Patent Document 1).

Patent Document 2 discloses a photosensitive resin composition using polyimide or polybenzoxazole.

### RELATED ART DOCUMENTS

### Patent Documents

[Patent Document 1] JP 2009-265520 A
[Patent Document 2] WO 2014/115233 A1

### SUMMARY OF THE INVENTION

An object of the invention is to provide a resin composition capable of forming a resin film in that the generation of cracks can be suppressed even if left stationary after development, a method of production of a cured product, a cured product, a patterned cured product, an interlayer insulating film, a cover coat layer, a surface protective film, and an electronic component.

According to the invention, the following resin composition and the like are provided.

1. A resin composition comprising:

the following component (A),

the following component (B), and

one or more selected from the group consisting of the following component (C) and the following component (D):

(A) polyimide, a polyimide precursor, polybenzoxazole, or a polybenzoxazole precursor

(B) one or more selected from the group consisting of a compound represented by the following formula (11), a compound represented by the following formula (21), and N-methyl-2-pyrrolidone

(C) a rust inhibitor

(D) a silane coupling agent

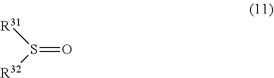

wherein in the formula (11), R³¹ and R³² are independently an alkyl group including 1 to 10 carbon atoms;

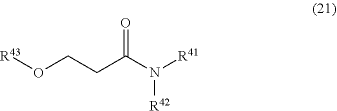

wherein in the formula (21), R⁴¹ to R⁴³ are independently an alkyl group including 1 to 10 carbon atoms.

2. The resin composition according to 1, wherein the component (A) is the polybenzoxazole precursor.
3. The resin composition according to 1 or 2, wherein the polybenzoxazole precursor is a polybenzoxazole precursor having a structural unit represented by the following formula (I):

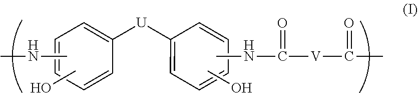

wherein in the formula (I), U is a divalent organic group, a single bond, —O— or —SO₂—, and V represents a divalent organic group.

4. The resin composition according to any one of 1 to 3, wherein the component (B) is the compound represented by the formula (11).
5. The resin composition according to any one of 1 to 4, wherein the component (C) is a nitrogen-containing heterocyclic compound.
6. The resin composition according to any one of 1 to 5, wherein the component (D) comprises one or more selected from the group consisting of a silane coupling agent having a hydroxy group (D1) and a silane coupling agent having a urea bond (D2).
7. The resin composition according to claim 6, wherein the content of the component (D1) is 0.1 to 20 parts by mass based on 100 parts by mass of the component (A).
8. The resin composition according to claim 6, wherein the content, of the component (D1) is 2.0 to 6.5 parts by mass based on 100 parts by mass of the component (A).
9. The resin composition according to any one of 6 to 8, wherein one or more selected from the group consisting of the component (C) and the component (D) are one or more selected from the group consisting of a triazole derivative, a tetrazole derivative, the component (D1), and the component (D2).
10. A resin composition according to any one of 1 to 9, which is a photosensitive resin composition.
11. A method of production of a cured product comprising steps of:

applying the resin composition according to any one of 1 to 10 on a substrate and drying to form a resin film, and

heat-treating the resin film.

12. A cured product obtained by curing a resin composition according to any one of 1 to 10.
13. A patterned cured product obtained by curing a resin composition according to 10.
14. An interlayer insulating film, a cover coat layer; or a surface protective film manufactured using the cured product according to 12 or the patterned cured product according to 13.
15. An electronic component comprising the interlayer insulating film, the cover coat layer, or the surface protective film according to 14.

According to the invention, a resin composition capable of forming a resin film in that the generation of cracks can be suppressed even if left stationary after development, a method of production of a cured product, a cured product, a patterned cured product, an interlayer insulating film, a cover coat layer, a surface protective film, and an electronic component can be provided.

### MODE FOR CARRYING OUT THE INVENTION

Embodiments of a resin composition, a method of production of a cured product, a cured product, a patterned cured product, an interlayer insulating film, a cover coat layer, a surface protective film, and an electronic component of the invention will be described in detail. However, the invention is not limited to the following embodiments.

In the specification, “A or B” may include either or both of A and B. Moreover, a term “step” herein includes not only an independent step, but also a step if expected action of the step is achieved, even when the step is not clearly distinguishable from other steps.

A numerical value range represented by using “to” indicates the range including numerical values described before and after “to” as a minimum value and a maximum value, respectively. Moreover, when a plurality of materials corresponding to each component exist in a composition, unless otherwise specified, a content of each component in the composition herein means a total amount of the plurality of materials existing in the composition. Further, unless otherwise specified, materials listed as examples may be used alone or in combination of two or more.

The resin composition of the invention comprises:

the following component (A),

the following component (B),

one or more selected from the group consisting of the following component (C) and the following component (D).

(A) polyimide, a polyimide precursor, polybenzoxazole, or a polybenzoxazole precursor (hereinafter also referred to as a “component (A)”)

(B) one or more selected from the group consisting of a compound represented by the following formula (11), a compound represented by the following formula (21), and N-methyl-2-pyrrolidone (hereinafter also referred to as a “component (B)”)

(C) a rust inhibitor (hereinafter also referred to as a “component (c)”)

(D) a silane coupling agent (hereinafter also referred to as a “component (D)”)

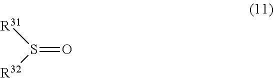

In the formula (11), R³¹ and R³² are independently an alkyl group including 1 to 10 carbon atoms.

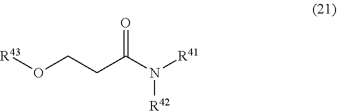

In the formula (21), R⁴¹ to R⁴³ are independently an alkyl group including 1 to 10 carbon atoms.

As a result, the resin composition of the invention allows the formation of a resin film in that the generation of cracks can be suppressed even if left stationary after development.

As an arbitrary effect a cured product having excellent adhesiveness to Cu can be formed.

As an arbitrary effect, a cured product having excellent adhesiveness to Cu even after performing the pressure cooker test (PCT) can be formed.

As an arbitrary effect, a cured product having excellent adhesiveness to Cu even after performing high-temperature storage (HTS) can be formed.

As an arbitrary effect, a cured product having excellent adhesiveness to SiN can be formed.

As an arbitrary effect, a cured product having excellent adhesiveness to SiN even after performing PCT can be formed.

As an arbitrary effect, a cured product having excellent adhesiveness to SiN even after performing HTS can be formed.

As an arbitrary effect, a cured product excellent in SAICAS (Surface And Interfacial Cutting Analysis System) evaluation on Cu can be formed.

As an arbitrary effect a cured product excellent in SAICAS evaluation on Cu even after performing PCT can be formed.

As an arbitrary effect, a cured product excellent in SAICAS evaluation on SiN can be formed.

As an arbitrary effect, a cured product excellent in SAICAS evaluation on SiN after PCT can be formed.

As an arbitrary effect, a cured product excellent in TEG (Test Element Group) evaluation on the patterned Cu can be formed.

As an arbitrary effect, a cured product excellent in TEG evaluation on patterned Cu even after performing PCT can be formed.

As an arbitrary effect, a cured product excellent in TEG evaluation on patterned Cu even after performing HTS can be formed.

As an arbitrary effect, a cured product excellent in TEG evaluation on the patterned SiN can be formed.

As an arbitrary effect, a cured product excellent in TEG evaluation on the patterned SiN even after performing PCT can be formed.

As an arbitrary effect, a cured product excellent in TEG evaluation on the patterned SiN even after performing HTS can be formed.

The resin composition preferably contains the component (A), the component (B), and the component (C) (more preferably further contains one or more selected from the group consisting of the component (D1) described later and the component (D2) described later, and

still more preferably contains the component (D1) described later and the component (D2) described later).

A resin composition preferably contains the component (A), the component (B), and the component (D1) described later (more preferably further contains the component (D2) described later, from the viewpoint of increasing adhesiveness).

A resin composition preferably contains the component (A), the component (B), and the component (D2) described later (more preferably further contains the component (D1) described later, from the viewpoint of increasing adhesiveness).

It is preferable that the component (A) has a high transmittance at the i-line from the viewpoint of patterning.

The component (A) is preferably a polybenzoxazole precursor.

The polybenzoxazole precursor is preferably a polybenzoxazole precursor having a structural unit represented by the following formula (I).

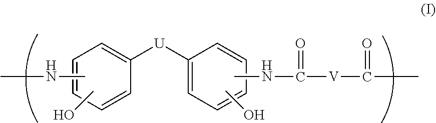

In the formula (I), U is a divalent organic group, a single bond, —O—, or —SO₂—, and V represents a divalent organic group.

Two benzene rings to which U in the formula (I) is bonded may independently have a substituent (e.g., a methyl group, a fluorine atom, an alkyl group, or a fluorinated alkyl group).

As the divalent organic group for U in the formula (I), a divalent aliphatic hydrocarbon group including 1 to 30 (preferably 2 to 30) carbon atoms which may have a substituent is preferred, and a methylene group which may have a substituent and an ethylene group which may have a substituent are more preferred.

A divalent aliphatic hydrocarbon group including 1 to 30 carbon atoms which may have a substituent for U in the formula (I) may be open-chain.

Examples of the substituent include a methyl group, a trifluoromethyl group, and the like.

The divalent organic group of U in the formula (I) is preferably a group represented by the following formula (UV1).

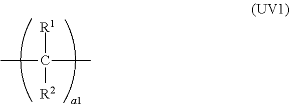

In the formula (UV1), R¹ and R² are independently a hydrogen atom, a fluorine atom, an alkyl group including 1 to 6 carbon atoms, or a fluorinated alkyl group including 1 to 6 carbon atoms, and a1 is an integer of 1 to 30 (preferably 1 to 10).

When two or more of each of R¹ and R² are present, the two or more of each of R¹ and R² may be the same as or different from each other.

Examples of the alkyl group including 1 to 6 (preferably 1 to 3) carbon atoms for R¹ and R² in the formula (UV1) include a methyl group, an ethyl group, and the like.

Examples of the fluorinated alkyl group including 1 to 6 (preferably 1 to 3) carbon atoms for R¹ and R² in the formula (UV1) include a trifluoromethyl group, a perfluorobutyl group, and the like.

R¹ and R² in the formula (UV1) are preferably trifluoromethyl groups from the viewpoint of transparency of the component (A).

Examples of the divalent organic group for V in the formula (I) include a group obtained by removing two carboxy groups from a dicarboxylic acid, and the like.

Examples of the divalent organic group for V in the formula (I) include a divalent aliphatic hydrocarbon group, a divalent aromatic hydrocarbon group, and the like.

In addition, the divalent organic group for V in the formula (I) may be a divalent group in which two divalent aromatic hydrocarbon groups are bonded through

a single bond;

a heteroatom such as an oxygen atom, a sulfur atom, a nitrogen atom, a silicon atom;

a group represented by the formula (UV1); or

an organic group such as a ketone group, an ester group, or an amide group.

The divalent aliphatic hydrocarbon group and the divalent aromatic hydrocarbon group may have a substituent. Examples of the substituent include a methyl group, an ethyl group, and the like.

Examples of the divalent aliphatic hydrocarbon group (preferably including 1 to 30 carbon atoms, and more preferably including 5 to 18 carbon atoms) include, for example, an alkylene group (e.g., a decylene group, and a dodecylene group), a cydopentylene group, a cyclohexylene group, a cyclooctylene group, a divalent bicyclo ring group, and the like.

Also, examples of the divalent aromatic hydrocarbon group (preferably including 6 to 30 carbon atoms) include a phenylene group, a naphthylene group, and the like.

In the formula (I), examples of the dicarboxylic add for V include dodecanedioic add, decanedioic acid, isophthalic add, terephthalic acid, 2,2-bis(4-carboxyphenyl)-1,1,1,3,3,3-hexafluoropropane, 4,4′-dicarboxybiphenyl, 4,4′-dicarboxydiphenyl ether, 4,4′-dicarboxytetraphenylsilane, bis(4-carboxyphenyl)sulfonic, 2,2-bis(p-carboxyphenyl)propane, 5-ted-butylisophthalic acid, 5-bromoisophthalic add, 5-fluoroisophthalic acid, 5-chloroisophthalic add, 2,6-naphthalenedicarboxylic acid, and the like.

The polybenzoxazole precursor having a structural unit represented by the formula (I) is preferably a polybenzoxazole precursor having a structural unit represented by the formula (II).

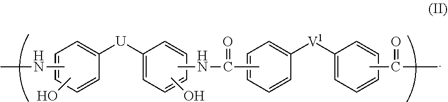

In the formula (II), U is as defined in the formula (I), V¹ is a divalent organic group, a single bond, —O—, or —SO₂—.

Examples of the divalent organic group for V¹ in the formula (II) include the same divalent organic group for U in the formula (I).

Two benzene rings to which V¹ in the formula (II) is bonded may independently have a substituent (e.g., a methyl group, a fluorine atom, an alkyl group, or a fluorinated alkyl group).

The component (A) is preferably soluble in an aqueous alkali solution, and more preferably soluble in an aqueous tetramethylammonium hydroxide (TMAH) solution.

One criterion that the component (A) is soluble in an aqueous alkali solution is described below. The component (A) is dissolved in an arbitrary solvent to form a solution, and the solution is spin-coated on a substrate such as a silicon wafer to form a resin film having a film thickness of about 5 μm. The obtained resin film is immersed in any one of an aqueous tetramethylammonium hydroxide solution, an aqueous metal hydroxide solution, and an aqueous organic amine solution at 20 to 25° C. As a result, when the resin film is dissolved into a solution, it is determined that the component (A) used is soluble in an aqueous alkali solution.

The polystyrene-converted weight-average molecular weight of the component (A) is preferably 10,000 to 100,000, more preferably 15,000 to 100,000, and still more preferably 17,000 to 85,000.

When the molecular weight of the component (A) is within the above range, it is possible to maintain appropriate solubility into an alkaline developer and to adjust the viscosity of the resin composition appropriately.

The weight-average molecular weight is determined by measuring by gel permeation chromatography and converting using a standard polystyrene calibration curve.

Further, the degree of dispersion obtained by dividing the weight-average molecular weight by the number-average molecular weight is preferably 1.0 to 4.0, and more preferably 1.0 to 3.5.

As the polybenzoxazole, a polybenzoxazole obtained by ring-closing the above-mentioned polybenzoxazole precursor is preferred.

The component (B) is preferably a compound represented by the formula (11).

Examples of the alkyl group including 1 to 10 (preferably 1 to 3, and more preferably 1 or 3) carbon atoms for R³¹ and R³² in the formula (11) include a methyl group, an ethyl group, a n-propyl group, an isopropyl group, a n-butyl group, a t-butyl group, a pentyl group, a hexyl group, a heptyl group, an octyl group, and the like.

The compound represented by the formula (11) is preferably dimethyl sulfoxide.

The compound represented by the formula (11) may be used alone or in combination of two or more.

Examples of the alkyl group including 1 to 10 (preferably 1 to 3, more preferably 1 or 3) carbon atoms of R⁴¹ to R⁴³ in the formula (21) include a methyl group, an ethyl group, a n-propyl group, an isopropyl group, a n-butyl group, a t-butyl group, a pentyl group, a hexyl group, a heptyl group, an octyl groups, and the like.

Examples of the compound represented by the formula (21), which is commercially available, include 3-methoxy-N,N-dimethylpropanamide (e.g., trade name “KJCMPA-100” (manufactured by KJ Chemicals Corporation).

The compound represented by the formula (21) may be used alone or in combination of two or more.

The content of the component (B) is not particularly limited, and is preferably from 3 to 40 parts by mass, and more preferably from 5 to 30 parts by mass, based on 100 parts by mass of the component (A).

From the viewpoint of the adhesiveness, the component (C) is preferably a nitrogen-containing heterocyclic compound.

Examples of the component (C) include, for example,

benzimidazole,

triazole derivatives such as 1,2,4-triazole, 1,2,3-triazole, 1,2,5-triazole, 3-mercapto-4-methyl-4H-1,2,4-triazole, 3-mercapto-1,2,4-triazole, 4-amino-3,5-dimethyl-4H-1,2,4-triazole, 4-amino-3,5-dipropyl-4H-1,2,4-triazole, 3-amino-5-isopropyl-1,2,4-triazole, 4-amino-3-mercapto-5-methyl-4H-1,2,4-triazole, 3-amino-5-mercapto-1,2,4-triazole, 3-amino-5-methyl-4H-1,2,4-triazole, 4-amino-1,2,4-triazole, 4-amino-3,5-dimethyl-1,2,4-triazole, 4-amino-5-methyl-4H-1,2,4-triazole-3-thiol, 3,5-diamino-1H-1,2,4-triazole, 5-methyl-1H-benzotriazole, 5,6-dimethylbenzotriazole, 5-amino-1H-benzotriazole, benzotriazole-4-sulfonic acid, and 1,2,3-benzotriazole, and tetrazole derivatives such as 1H-tetrazole, 5-methyl-1H-tetrazole, 5-(methylthio)-1H-tetrazole, 5-(ethylthio)-1H-tetrazole, 5-phenyl-1H-tetrazole, 5-nitro-1H-tetrazole, 1-methyl-1H-tetrazole, 5,5′-bis-1H-tetrazole, and 5-amino-1H-tetrazole.

The component (C) is preferably benzotriazole (1,2,3-benzotriazole) or 5-amino-1H-tetrazole.

The component (C) may be used alone or in combination of two or more.

When the component (C) is used, the content of the component (C) is preferably from 0.01 to 10 parts by mass, more preferably from 0.1 to 5 parts by mass, and still more preferably from 0.3 to 5 parts by mass, based on 100 parts by mass of the component (A).

The component (D) may be used alone or in combination of two or more.

When the component (D) is used, the content of the component (D) is preferably from 0.1 to 20 parts by mass, more preferably from 0.3 to 10 parts by mass, and still more preferably from 1 to 10 parts by mass, based on 100 parts by mass of the component (A).

From the viewpoint of increasing the adhesiveness, it is preferable that the component (0) contains one or more selected from the group consisting of a silane coupling agent having a hydroxy group (D1) (hereinafter, also referred to as a “component (D1)”) and a silane coupling agent having a urea bond (—NH—CO—NH—) (D2) (hereinafter, also referred to as a “component (D2)”).

It is preferable that the component (D) contains the component (D1).

As the component (D1), a compound represented by the formula (6) is preferred in order to further increase adhesiveness to a substrate.

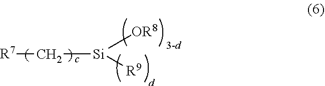

In the formula (6), R⁷ is a monovalent group having a hydroxy group (e.g., a hydroxy group, a bis(2-hydroxyethyl)amino group, or a bis(2-hydroxymethyl)amino group), R⁸ and R⁹ are independently an alkyl group including 1 to 5 carbon atoms (e.g., a methyl group, and an ethyl group); c is an integer of 1 to 10 (preferably 1, 2, 3, or 4), and d is an integer of 0 to 3 (preferably 0 or 1).

Examples of the compound represented by the formula (6) include hydroxymethyltrimethoxysilane, hydroxymethyltriethoxysilane, 2-hydroxyethyltrimethoxysilane, 2-hydroxyethyltriethoxysilane, 3-hydroxypropyltrimethoxysilane, 3-hydroxypropyltriethoxysilane, 4-hydroxybutyltrimethoxysilane, 4-hydroxybutyltriethoxysilane, and the like.

The component (D1) preferably further has a group including a nitrogen atom, and is preferably a silane coupling agent further having an amino group or an amide bond.

Examples of the silane coupling agent further having an amino group include bis(2-hydroxymethyl)-3-aminopropyltrimethoxysilane, bis(2-hydroxyethyl)-3-aminopropyltrimethoxysilane, bis(2-hydroxyethyl)-3-aminopropyltriethoxysilane, bis(2-hydroxymethyl)-3-aminopropyltriethoxysilane, and the like.

Examples of the silane coupling agent further having an amide bond include a compound represented by R¹⁰—(CH₂)ₑ—CO—NH—(CH₂)ₜ—Si(OR^{10A})₃, wherein R¹⁰ is a hydroxy group, e and f are independently an integer of 1 to 3, and RCA is a methyl group, an ethyl group, or a propyl group; and the like.

The component (D1) may be used alone or in combination of two or more.

When the component (D1) is used, the content of the component (D1) is preferably from 0.1 to 20 parts by mass, more preferably from 0.3 to 10 parts by mass, still more preferably from 1 to 8 parts by mass, and particularly preferably from 2.0 to 6.5 parts by mass, based on 100 parts by mass of the component (A).

It is preferable that the component (D) contains the component (D2).

The component (D2) is preferably a compound represented by the following formula (7).

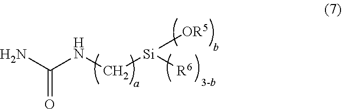

In the formula (7), R⁵ and R⁶ are independently an alkyl group including 1 to 5 carbon atoms (e.g., a methyl group, and an ethyl group); a is an integer of 1 to 10 (preferably 1, 2, 3, or 4), and b is an integer of 1 to 3 (preferably 2 or 3).

Specific examples of the compound represented by the formula (7) include ureidomethyltrimethoxysilane, ureidomethyltriethoxysilane, 2-ureidoethyltrimethoxysilane, 2-ureidoethyltriethoxysilane, 3-ureidopropyltrimethoxysilane, 3-ureidopropyltriethoxysilane, 4-ureidobutyltrimethoxysilane, 4-ureidobutyltriethoxysilane, and the like, and 3-ureidopropyttriethoxysilane is preferable.

The component (02) may be used alone or in combination of two or more.

When the component (D2) is used, the content of the component (D2) is preferably from 0.1 to 20 parts by mass, more preferably from 0.3 to 10 parts by mass, and still more preferably from 1 to 10 parts by mass, based on 100 parts by mass of the component (A).

As the compound (D), a silane coupling agent having a glycidyl group (D3) (hereinafter also referred to as a “component (03)”) may be used.

Examples of the component (D3) include glycidoxymethyltrimethoxysilane, glycidoxymethyltriethoxysilane, 2-glycidoxyethyltrimethoxysilane, 2-glycidoxyethyltriethoxysilane, 3-glycidoxypropyltrimethoxysilane, 3-glycidoxypropyltriethoxysilane, 4-glycidoxybutyltrimethoxysilane, 4-glycidoxybutyltriethoxysilane, bis(2-glycidoxymethyl)-3-aminopropyltriethoxysilane, and the like.

The component (D3) may be used alone or in combination of two or more.

When the component (D3) is used, the content of the component (0) is preferably from 0.1 to 20 parts by mass, more preferably from 0.3 to 10 parts by mass, and still more preferably from 0.4 to 10 parts by mass, based on 100 parts by mass of the component (A).

As the component (D), 3-mercaptopropyltrimethoxysilane, methylphenylsilanediol, ethyiphenylsilanediol, n-propylphenylsilanediol, isopropylphenylsilanediol, n-butylphenylsilanediol, isobutylphenylsilanediol, tert-butylphenylsilanediol, diphenylsilanediol, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl(n-propyl)phenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, phenylsilanetiol, 1,4-bis(trihydroxysilyl)benzene, 1,4-bis(methyldihydroxysilyl)benzene, 1,4-bis(ethyldihydroxysilyl)benzene, 14-bis(propyldihydroxysilyl)benzene, 14-bis(butyldihydroxysilyl)benzene, 14 bis(dimethylhydroxysilyl)benzene, 1,4-bis(diethylhydroxysilyl)benzene, 1,4-bis(dipropylhydroxysilyl)benzene, 1,4-bis(dibutylhydroxysilyl)benzene, and the like can also be used.

From the viewpoint of increasing adhesiveness, the one or more selected from the group consisting of the component (C) and the component (D) are preferably one or more selected from the group consisting of a triazole derivative, a tetrazole derivative, the component (D1), and the component (D2).

The resin composition of the invention may further contain a photosensitive agent.

The photosensitive agent has a function of generating a difference in the solubility into a developer between an irradiated portion and an unirradiated portion in solubility with respect to a developer in response to irradiation light, when light is irradiated onto a photosensitive resin film formed by applying a photosensitive resin composition (e.g., a composition obtained by blending a photosensitive agent to the above-described resin composition) on a substrate.

The photosensitive agent is not particularly limited, and it is preferable that the photosensitive agent is a compound which generates an acid by light (photoacid generator). Thus, the photosensitive agent has a function of increasing the solubility of the portion irradiated with light with respect to an aqueous alkali solution.

Examples of the active light include an ultraviolet ray such as an i-line, a visible ray, and a radioactive ray.

Examples of the photoacid generator include a diazonaphthoquinone compound, an aryldiazonium salt, a diaryliodonium salt, and a triarylsutfonium salt, and among these, a diazonaphthoquinone compound is preferred from the viewpoint of exhibiting good sensitivity.

A diazonaphthoquinone compound is a compound having a diazonaphthoquinone structure.

A diazonaphthoquinone compound is obtained, for example, by condensation reaction of o-quinonediazidosulfonyl chlorides with a hydroxy compound, an amino compound, or the like (preferably a hydroxy compound) in the presence of a dehydrochlorinating agent.

As the o-quinonediazidosulfonyl chlorides, for example, 1,2-benzoquinone-2-diazido-4-sulfonyl chloride, 1,2-naphthoquinone-2-diazido-5-sulfonyl chloride, 1,2-naphthoquinone-2-diazido-4-sulfonyl chloride, and the like can be used.

As the hydroxy compound, for example, hydroquinone, resorcinol, pyrogallol, bisphenol A, bis(4-hydroxyphenyl)methane, 2,2-bis(4-hydroxyphenyl)hexafluoropropane, 2,3,4,-trihydroxybenzophenone, 2,3,4,4′-tetrahydroxybenzophenone, 2,2′,4,4′-tetrahydroxybenzophenone, 2,3,4,2′,3′-pentahydroxybenzophenone, 2,3,4,3,4′,5′-hexahydroxybenzophenone, bis(2,3,4-trihydroxyphenyl)methane, bis(2,3,4-trihydroxyphenyl)propane, 4b,5,9b,10-tetrahydro-1,3,6,8-tetrahydroxy-5,10-dimethylindeno[2,1-a]indene, tris(4-hydroxyphenyl)methane, tris(4-hydroxyphenyl)ethane, 1,1-bis(4-hydroxyphenyl)-1-([2-(4-hydroxyphenyl)-2-propyl]phenyl)ethane, and the like can be used.

As the amino compound, for example, p-phenylenediamine, m-phenylenediamine, 4,4′-diaminodiphenyl ether, 4,4′-diaminodiphenyl methane, 4,4″-diaminodiphenyl sulfone, 4,4′-diaminodiphenyl sulfide, o-aminophenol, m-aminophenol, p-aminophenol, 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, bis(3-amino-4-hydroxyphenyl)hexafluoropropane, bis(4-amino-3-hydroxyphenyl)hexafiuoropropane, and the like can be used.

When a photosensitive agent is contained, the content of the photosensitive agent is preferably from 0.01 to 50 parts by mass, more preferably from 0.1 to 30 parts by mass, still more preferably from 0.5 to 25 parts by mass, and particularly preferably from 3 to 20 parts by mass, based on 100 parts by mass of the component (A), from the viewpoint of sensitivity and resolution at the time of exposure to light

In view of increasing mechanical properties and chemical resistance, the resin composition of the invention may further contain a crosslinking agent.

Examples of the crosslinking agent include a compound represented by the following formula (2) and the like.

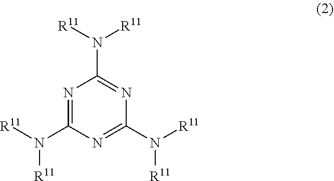

In the formula (2), R¹¹'s are independently a hydrogen atom or a group represented by —CH₂—O—R¹². At least one (preferably all) of R¹¹'s is the group represented by the —CH₂—O—R¹². R¹² is a hydrogen atom or an alkyl group including 1 to 6 carbon atoms, and when two or more R¹²'s are present, the two or more R¹²'s may be the same as or different from each other.

Examples of the alkyl group including 1 to 6 (preferably 1, 2, or 3) carbon atoms for R¹² in the formula (2) include a methyl group, an ethyl group, a butyl group, and the like.

Further, examples of the crosslinking agent include, for example, a compound represented by the following formula (3).

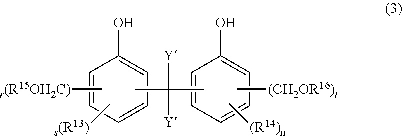

In the formula (3), a plurality of Y′ is independently a hydrogen atom, an alkyl group including 1 to 10 (preferably 1 to 5) carbon atoms, a fluoroalkyl group including 1 to 10 (preferably 1 to 5) carbon atoms partially or fully substituted with a fluorine atom (e.g., a trifluoromethyl group), a hydroxyalkyl group including 1 to 10 (preferably 1 to 5) carbon atoms partially substituted with a hydroxy group, or an alkoxy group including 1 to 10 (preferably 1 to 5) carbon atoms; R¹³ and R¹⁴ independently represent a monovalent organic group; R¹⁵ and R¹⁶ independently represent a hydrogen atom or a monovalent organic group; r and t are independently an integer of 1 to 3 (preferably 1 to 2); and s and u are independently an integer of 0 to 3 (preferably 0 to 1).

As the monovalent organic group for R¹⁵ and R¹⁶ in the formula (3), an alkyl group including 1 to 10 (preferably 1 to 5) carbon atoms, a hydroxyalkyl group including 1 to 10 (preferably 1 to 5) carbon atoms, an alkyl group including 1 to 10 (preferably 1 to 5) carbon atoms which is partially or fully substituted with a halogen atom (e.g., trifluoromethyl group), and a hydroxyalkyl group including 1 to 10 (preferably 1 to 5) carbon atoms which is partially or fully substituted with a halogen atom are preferable.

As the monovalent organic group for R¹³ and R¹⁴ in the formula (3), an alkyl group including 1 to 10 (preferably 1 to 5) carbon atoms, an alkoxy group including 1 to 10 (preferably 1 to 5) carbon atoms, a hydroxyalkyl group including 1 to 10 (preferably 1 to 5) carbon atoms, a hydroxyalkoxy group including 1 to 10 (preferably 1 to 5) carbon atoms, an alkoxyalkyl group including 2 to 10 (preferably 2 to 5) carbon atoms, an alkyl group including 1 to 10 (preferably 1 to 5) carbon atoms which is partially or fully substituted with a halogen atom (e.g., trifluoromethyl group), an alkoxy group including 1 to 10 (preferably 1 to 5) carbon atoms which is partially or fully substituted with a halogen atom, a hydroxyalkyl group including 1 to 10 (preferably 1 to 5) carbon atoms which is partially or fully substituted with a halogen atom, a hydroxyalkoxy group including 1 to 10 (preferably 1 to 5) carbon atoms which is partially or fully substituted with a halogen atom, and an alkoxyalkyl group including 2 to 10 (preferably 2 to 5) carbon atoms which is partially or fully substituted with a halogen atom are preferable.

Examples of the alkyl group including 1 to 10 carbon atoms of the monovalent organic group for Y′ and R¹³ to R¹⁶ in the formula (3) include a methyl group, an ethyl group, and the like.

Examples of the hydroxyalkyl group including 1 to 10 carbon atoms of the monovalent organic group for Y′ and R¹³ to R¹⁶ in the formula (3) include a methylol group and the like.

Examples of the alkoxy group including 1 to 10 carbon atoms of the monovalent organic group for Y′ and R¹³ to R¹⁶ in the formula (3) include a methoxy group, an ethoxy group, and the like.

Examples of the halogen atom of the monovalent organic group for Y′ and R¹³ to R¹⁶ in the formula (3) include a fluorine atom and the like.

Examples of the alkoxyalkyl group including 2 to 10 carbon atoms of the monovalent organic group for Y′ and R¹³ to R¹⁶ in the formula (3) include a methoxymethyl group, an ethoxymethyl group, an ethoxyethyl group and the like.

Further, as a crosslinking agent, for example, the following compound may be used.

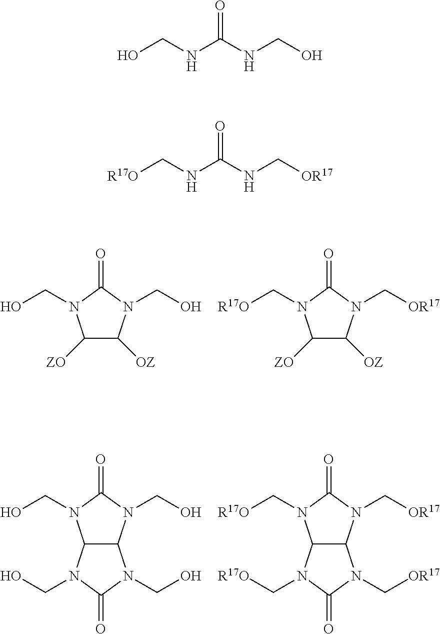

In the formulas, Z's independently represent an alkyl group including 1 to 6 carbon atoms, and R¹⁷'s independently represent an alkyl group including 1 to 6 carbon atoms.

Examples of the alkyl group including 1 to 6 (preferably 1, 2, or 3) carbon atoms for R¹⁷ and Z include a methyl group, an ethyl group, a butyl group, and the like.

The crosslinking agent may be used alone or in combination of two or more.

When a crosslinking agent is contained, the content of the crosslinking agent is preferably 1 part by mass or more, more preferably from 1.5 to 50 parts by mass, and still more preferably from 2 to 30 parts by mass, based on 100 parts by mass of the component (A).

In view of the residual film ratio and the development time adjustment, the resin composition of the invention may further contain a dissolution adjuster or a dissolution inhibitor. By using a dissolution adjuster or a dissolution inhibitor, the contrast of the dissolution rate between the exposed portion and the unexposed portion can be increased, so that a precise pattern can be formed.

Examples of the dissolution adjuster include an iodonium salt, an ammonium salt a phosphonium salt, and the like.

The dissolution adjuster may be used alone or in combination of two or more.

When a dissolution adjuster is contained, the content of the dissolution adjuster is preferably 0.1 parts by mass or more, more preferably from 0.2 to 15 parts by mass, and still more preferably from 0.3 to 10 parts by mass, based on 100 parts by mass of the component (A).

The resin composition of the invention may further contain a cyclization promoter.

Examples of the cyclization promoter include a thermal add generator, a thermal base generator, and the like.

The thermal add generator preferably generates a strong add, and specifically, as such a strong acid, for example, arylsulfonic adds such as p-toluenesulfonic acid and benzenesulfonic acid,

camphorsulfonic acid,

perfluoroalkylsulfonic adds such as trifluoromethanesulfonic add and nonafluorobutanesulfonic acid, and

alkylsulfonic adds such as methanesulfonic add, ethanesulfonic add, and butane sulfonic acid, and the like are preferred.

As the thermal acid generator, an onium salt of the above strong add, a salt of the above strong add and a pyridine derivative, and an imidosulfonate with which the above strong acid is covalently bonded are preferred.

As the onium salt, for example, diaryliodonium salts such as a diphenyliodonium salt,

di(alkylaryl)iodonium salts such as a di(t-butylphenyl)iodonium salt,

trialkylsulfonium salts such as a trimethyisulfonium salt,

dialkylmonoarylsulfonium salts such as a dimethylphenylsulfonium salt, and

diarylmonoalkyliodonium salts such as a diphenylmethylsulfonium salt are preferred.

Examples of the thermal acid generator include cyclohexyl p-toluenesulfonate, isopropyl p-toluenesulfonate, 2,4,6-trimethylpyridinium p-toluenesulfonate, isopropyl methanesulfonate, and the like.

As a base which the thermal base generator generates, for example, an amine compound can be given. A secondary amine or a tertiary amine is preferred, and a tertiary amine is more preferred because the basic property is high and the heat treatment temperature of the resin film can be further lowered.

In addition, the boiling point of the base the thermal base generator generates is preferably 80° C. or higher, more preferably 100° C. or higher, and most preferably 140° C. or higher.

Examples of the thermal base generator include carboxylic acid compounds such as N-phenyliminodiacetic acid, salts of 1,8-diazabicyclo[5.4.0]undeca-7-ene (DBU), and the like.

The cyclization promoter may be used alone or in combination of two or more.

When a cyclization promoter is contained, the content of the cyclization accelerator is preferably 0.1 parts by mass or more, more preferably from 0.3 to 10 parts by mass, and still more preferably from 0.5 to 5 parts by mass, based on 100 parts by mass of the component (A).

The resin composition of the invention may further contain a solvent.

The solvent is not particularly limited in usual as long as it can dissolve other components, and examples thereof include γ-butyrolactone, ethyl lactate, propylene glycol monomethyl ether acetate, benzyl acetate, n-butyl acetate, ethoxyethylpropionate, 3-methylmethoxypropionate, N,N-dimethylformamide, N,N-dimethylacetamide, hexamethylphosphorylamide, tetramethylenesulfone, cyclohexanone, cydopentanone, diethylketone, diisobutylketone, methylamylketone, and the like.

Among these, γ-butyrolactone, ethyl lactate, propylene glycol monornethyl ether acetate, N,N-dimethylformamide, and N,N-dimethylacetamide are preferred from the viewpoint of solubility of each component and from the viewpoint of coating property.

The solvent may be used alone or in combination of two or more.

The content of the content of the solvent is not particularly limited, and is usually 1 to 1000 parts by mass, preferably from 50 to 300 parts by mass, and more preferably from 100 to 200 parts by mass, based on 100 parts by mass of the component (A).

The resin composition of the invention may further contain a dissolution promoter, a surfactant, a leveling agent, and the like.

By containing a dissolution promoter; the solubility of the component (A) in an aqueous alkali solution can be further promoted.

Examples of the dissolution promoter include a compound having a phenolic hydroxy group, for example. By using a dissolution promoter, when developing using an aqueous alkali solution, the dissolution rate of an exposed portion increases, and the sensitivity can be increased. In addition, melting of a resin film can be prevented at the time of curing of the resin film after pattern formation.

The compound having a phenolic hydroxy group is not particularly limited, and a compound having a relatively small molecular weight is preferred.

Examples of the compound having a phenolic hydroxy group include o-cresol, m-cresol, p-cresol, 2,4-xylenol, 2,5-xylenol, 2,6-xylenol, bisphenol A, bisphenol B, bisphenol C, bisphenol E, bisphenol F bisphenol G, 4,4′,4″-methylidine trisphenol, 2,6-[(2-hydroxy-5-methylphenyl)methyl]-4-methylphenol, 4,4′-[1-[4-[1-(4-hydroxyphenyl)-1-methylethyl]phenyl]ethylidene]bisphenol, 4,4′-[1-[4-[2-(4-hydroxyphenyl)-2-propyl]phenyl]ethylidene]bisphenol, 4,4′,4″-ethylidene trisphenol, 4-[bis(4-hydroxyphenyl)methyl]-2-ethoxyphenol, 4,4′-[(2-hydroxyphenyl)methylene]bis[2,3-dimethylphenol], 4,4′-[(3-hydroxyphenyl)methylene]bis[2,6-dimetylphenol], 4,4′-[(4-hydroxyphenyl)methylene]bis[2,6-dimethylphenol], 2,2′-[(2-hydroxyphenyl)methylene]bis[3,5-dimethylphenol], 2,2″-[(4-hydroxyphenyl)methylene]bis[3,5-dimethylphenol], 4,4′-[(3,4-dihydroxyphenyl)methylene]bis[2,3,6-trimethylphenol], 4-[bis(3-cyclohexyl-4-hydroxy-6-methylphenyl)methyl]-1,2-benzenediol, 4,6-bis[(3,5-dimethyl-4-hydroxyphenyl)methyl]-1,2,3-benzenetriot 4,4′4-[(2-hydroxyphenyl)methylene]bis[3-methylphenol], 4,4′,4″-(3-methyl-1-propanyl-3-ylidine)trisphenol, 4,4′,4″,4″-(1,4-phenylenedimethylidine)tetrakisphenol, 2,4,6-tris[(3,5-dimethyl-4-hydroxyphenyl)methyl]-1,3-benzenediol, 2,4,6-tris[(3,5-dimethyl-2-hydroxyphenyl)methyl]-1,3-benzenediol, 4,4′-[1-[4-[1-(4-hydroxyphenyl)-3,5-bis[(hydroxy-3-methylphenyl)methyl]phenyl]phenyl]ethylidene]bis[2,6-bis(hydroxy-3-methylphenyl)methyl]phenol, and the like.

When a dissolution promoter is contained, the content of the dissolution promoter is preferably from 1 to 30 parts by mass, and more preferably from 3 to 25 parts by mass, based on 100 parts by mass of the component (A), from the viewpoint of development time and sensitivity.

By containing a surfactant or a leveling agent, coating property, for example, suppression of striation (unevenness in film thickness), and developability can be increased.

Examples of the surfactant or the leveling agent include, for example, polyoxyethylene urallyl ether, polyoxyethylene stearyl ether, polyoxyethylene oleyl ether, and polyoxyethylene octylphenol ether, and examples of the commercially available product thereof include a trade name “Megaface F171,” “F173,” “R-08” (manufactured by DIC Corporation), a trade name “Florard FC430,” “FC431” (manufactured by 3M Japan Limited), and a trad name “organosiloxane polymer KP341,” “KBM303:” “KBM403,” and “KBM803” (manufactured by Shin-Etsu Chemical Co., Ltd.), and the like.

Each of the surfactant and the leveling agent may be used alone or in combination of two or more.

When a surfactant or a leveling agent is contained, the content of the surfactant or the leveling agent is preferably from 0.01 to 10 parts by mass, more preferably from 0.05 to 5 parts by mass, and still more preferably from 0.05 to 3 parts by mass, based on 100 parts by mass of the component (A).

The resin composition of the invention consists essentially of, other than a solvent, one or more selected from the group consisting of a component (C) and a component (D), a component (A), and a component (B), and optionally, a photosensitive agent, a crosslinking agent, a dissolution adjuster, a cyclization promoter, a dissolution promoter, a surfactant, and a leveling agent, and may contain other unavoidable impurities within a range not impairing the effect of the invention.

Except for a solvent, for example, 80% by mass or more, 90% by mass or more, 95% by mass or more, 98% by mass or more or 100% by mass of the resin composition of the invention consists of

one or more selected from the group consisting of a component (C) and a component (D), a component (A), and a component (B), or

one or more selected from the group consisting of a component (C) and a component (D), a component (A), and a component (B), and optionally, a photosensitive agent, a crosslinking agent, a dissolution adjuster, a cyclization promoter, a dissolution promoter, a surfactant, and a leveling agent.

The resin composition of the invention is preferably a photosensitive resin composition, and more preferably a positive photosensitive resin composition.

The cured product of the invention can be obtained by curing the resin composition described above.

The cured product of the invention may be used as a patterned cured product or a cured product without a pattern.

The thickness of the cured product of the invention is preferably 3 to 30 μm.

A method of production of a cured product of the invention includes steps of applying the above-described resin composition on a substrate and drying to form a resin film, and heat-treating the resin film. The method may further include a step of exposing, for example, without a pattern, and developing.

By the above-mentioned method, a cured product of the invention can be obtained.

The method of production of a patterned cured product described above includes, for example, steps of: applying the above-described resin composition (preferably further containing a photosensitive agent and a crosslinking agent) on a substrate and drying to form a resin film; pattern-exposing the resin film to obtain a resin film after pattern exposure; developing the resin film after pattern exposure using an aqueous alkali solution to obtain a patterned resin film; and heat-treating the patterned resin film.

By the above-mentioned method, a patterned cured product can be obtained.

Examples of the substrate include semiconductor substrates such as a Si substrate (silicon wafer), a glass substrate, a silicon carbide substrate, a lithium tantalate substrate, and a lithium niobate substrate; metal oxide insulator substrates such as a TiO₂ substrate, a SiO₂ substrate; a Cu plated wafer, a silicon nitride substrate (for example, a wafer with SiN layer formed), an aluminum substrate, a copper substrate, a copper alloy substrate, and the like.

Examples of the application method of a resin composition on a substrate include an immersion method, a spraying method, a screen-printing method, a spin-coating method, and the like. The application method is not particularly limited, and can be performed using a spinner or the like.

The drying can be performed using a hot plate, an oven, or the like.

The drying temperature is preferably from 70 to 150° C., and more preferably from 90 to 120° C. from the viewpoint of ensuring dissolution contrast. The drying time is preferably from 30 seconds to 5 minutes.

The drying may be performed twice or more times. By this, a resin film which is formed of the above-described resin composition into a film shape can be obtained.

The thickness of the resin film is preferably from 2 to 100 μm, more preferably from 3 to 50 μm, and still more preferably from 5 to 30 μm.

In the pattern exposure, for example, a predetermined pattern is obtained by exposure of light through a photomask. In the exposure performed without a pattern, for example, light is exposed without using a photomask.

For light exposure, i-line is preferable, but as the active light to be irradiated, ultraviolet rays, far ultraviolet rays, visible rays, electron beams, X-rays, and the like can be used.

As an exposure equipment, a parallel exposure machine, a projection exposure machine, a stepper, a scanner exposure machine, a proximity exposure machine, and the like can be used.

As a result of development, a resin film with a pattern, that is, a patterned resin film can be obtained.

The developer is not particularly limited, and flame-retardant solvents such as 1,1,1-trichloroethane; aqueous alkali solutions such as an aqueous solution of sodium carbonate, and an aqueous solution of tetramethylammonium hydroxide; good solvents such as N,N-dimethylformamide, dimethylsulfoxide, N,N-dimethylacetamide, N-methyl-2-pyrrolidone, cyclopentanone, γ-butyrolactone, and an acetate ester; a mixed solvent of the good solvent with a poor solvent such as a lower alcohol, water, or an aromatic hydrocarbon, and the like are used. After development, rinse washing may be performed with a poor solvent or the like if necessary.

A surfactant may be added to the developer. The surfactant is preferably added in an amount of from 0.01 to 10 parts by mass and more preferably from 0.1 to 5 parts by mass based on 100 parts by mass of the developer.

The development time may be, for example, a time until when the film thickness of the unexposed portion after development becomes 60 to 90% of the film thickness after drying. The development time varies depending on the component (A) used, and is preferably from 10 seconds to 15 minutes, more preferably from 10 seconds to 5 minutes, and still more preferably from 20 seconds to 5 minutes from the viewpoint of productivity.

After development, washing may be performed with a rinse solution.

As the rinse solution, distilled water, methanol, ethanol, isopropanol, toluene, xylene, propylene glycol monomethyl ether acetate, propylene glycol monomethyl ether, or the like may be used alone or as a mix as appropriate, or may be used in combination in change step by step.

A patterned cured product can be obtained by heat-treating the pattern resin film.

Further, by subjecting the resin film to heat treatment, a cured product can be obtained.

A polybenzoxazole precursor of the component (A) may undergo a dehydration ring-closing reaction by a heat treatment step to obtain the corresponding polybenzoxazole.

The heat treatment temperature is preferably 400° C. or lower, more preferably 150 to 350° C. When the heat treatment temperature is 180° C. or higher, the cyclization reaction proceeds sufficiently, and good heat resistance tends to be obtained.

When the heat treatment temperature is within the above range, damage to the substrate and the device can be suppressed to a small level, the device can be produced with a high yield, and energy saving of the process can be realized.

The heat treatment time is preferably 5 hours or shorter, more preferably 30 minutes to 3 hours.

When the heat treatment time is within the above range, the crosslinking reaction or the dehydration ring-closing reaction can sufficiently proceed.

The atmosphere of the heat treatment may be in an air atmosphere or an inert atmosphere such as nitrogen, and is preferably under a nitrogen atmosphere from the viewpoint that a resin film, a pattern resin film, and a substrate are prevented from oxidation.

Examples of the apparatus used for the heat treatment include a quartz tube oven, a hot plate, a rapid thermal annealing, a vertical diffusion furnace oven, an infrared curing oven, an electron beam curing oven, a microwave curing oven, and the like.

The cured product of the invention can be used as a passivation film, a buffer coat film, an interlayer insulating film, a cover coat layer, a surface protective film, or the like.

With the use of one or more selected from the group consisting of the passivation film, the buffer coat film, the interlayer insulating film, the cover coat layer, the surface protective film, and the like, highly reliable electronic components such as semiconductor devices, multilayer wiring boards, and various electronic devices can be fabricated.

### EXAMPLES

Hereinafter, the invention will be described more specifically on the basis of Examples and Comparative Examples. The invention is not limited to the following Examples.

### Synthesis Example 1 [Synthesis of Polybenzoxazole Precursor A1]

A 0.5-liter flask equipped with an stirrer and a thermometer was charged with 15.48 g (60 mmol) of 4,4′-dicarboxydiphenyl ether and 90 g of N-methyl-2-pyrrolidone, and the flask was cooled to 5′C. Thereafter, 23.9 g (120 mmol) of thionyl chloride was added dropwise to the flask and reacted for 30 minutes to obtain a solution of 4,4′-diphenyl ether tetracarboxylic add chloride.

Then, 87.5 g of N-methyl-2-pyrrolidone was placed in a 0.5-liter flask equipped with a stirrer and a thermometer, and 18.30 g (50 mmol) of 2,2-bis(3-amino-4-hydroxyphenyl)-1,1,1,3,3,3-hexafluoropropane and 2.2 g (20 mmol) of p-aminophenol were added thereto, and the mixture was dissolved with stirring. Thereafter. 9.48 g (120 mmol) of pyridine was added to the flask, and a solution of 4,4′-diphenyl ether dicarboxylic acid chloride was added thereto dropwise over 30 minutes while the temperature was kept at 0 to 5° C., and the solution in the flask was stirred for 30 minutes. The above solution was poured into 3 L of water, and the precipitates were collected, washed 3 times with pure water, and then reduced in pressure to obtain a polybenzoxazole precursor A1.

The weight-average molecular weight of the obtained polybenzoxazole precursor A1 was 19,810.

The molecular weight was measured by gel permeation chromatography and converted with standard polystyrene calibration curve. The measurement conditions of the weight-average molecular weight are as follows.

Measuring apparatus: Detector SPD-M20A, manufactured by Shimadzu Corporation

Pump: LC-20AD manufactured by Shimadzu Corporation

Measurement conditions: Columns: two Gelpack GL-S300MDT-5

Eluent: tetrahydrofuran (THF)/dimethylformamide (DMF)=1/1 (volume ratio)

LiBr (0.03 mol/L), H₃PO₄ (0.06 mol/L)

Flow rate: 1.0 mL/min, detector UV 270 nm

Measurement was conducted by using a solution of 1 mL of solvent [THF/DMF=1/1 (volume ratio)] per 5 mg of a sample (precursor).

### Examples 1 to 8 and Comparative Examples 1 to 4

### (Preparation of Resin Composition)

The resin compositions of Examples 1 to 8 and Comparative Examples 1 to 4 were prepared with the components in the blending amount shown in Table 1. The blending amounts described in Table 1 are indicated as parts by mass of each component with respect to 100 parts by mass of A1.

The components used are as follows. As the component (A), A1 obtained in Synthetic Example 1 was used.

### Component (B)

B1: dimethylsulfoxide (manufactured by Tokyo Chemical Industry Co, Ltd.)
B2: KJCMPA-100 (the compound represented by the following formula E2, manufactured by KJ Chemicals Corporation):

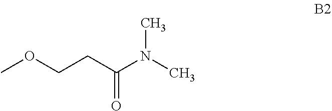

### Component (C)

C1: 1,2,3-benzotriazole (manufactured by Tokyo Chemical Industry Co., Ltd.)
C2: 5-amino-1H-tetrazole (manufactured by Tokyo Chemical Industry Co., Ltd.)

### Component (D)

D1: bis(2-hydroxyethyl)-3-aminopropyltriethoxysilane
D2: 3-ureidopropyltriethoxysilane
D3: 3-glycidoxypropyltrimethoxysilane (KBM-403, manufactured by Shin-Etsu Chemical Co., Ltd.)

### Component (E)

E1: the compound represented by the following formula:

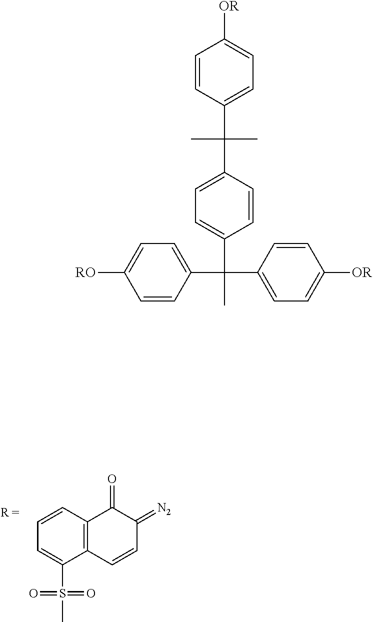

Crosslinking agent (component (F))
F1: 5,5′-[2,2,2-trifluoro-1-(trifluoromethyl)ethylidene]bis[2-hydroxy-1,3-benzenedimethanol]
F2: the compound represented by the following formula:

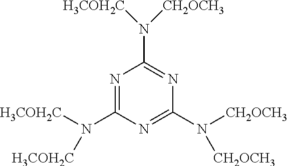

TABLE 1

| | | Ex. 1 | Ex. 2 | Ex. 3 | Ex. 4 | Ex. 5 | Ex. 6 | Ex. 7 | Ex. 8 | Comp. Ex. 1 | Comp. Ex. 2 |
|---|---|---|---|---|---|---|---|---|---|---|---|
| Component (A) | A1 | 100 | 100 | 100 | 100 | 100 | 100 | 100 | 100 | 100 | 100 |
| Component (B) | B1 | 15 | 15 | 15 | 15 | 15 | 15 | 15 | — | — | — |
| | B2 | — | — | — | — | — | — | — | 15 | — | — |
| Component (C) | C1 | — | 0 5 | — | 0 5 | 1 | 2 | 0.5 | 0.5 | — | — |
| | C2 | — | — | 0.5 | 0.5 | — | — | — | — | — | — |
| Component (D) | D1 | 3 | 3.5 | 3.5 | 3.5 | 3.5 | 3.5 | 6 | 3.5 | 3 | — |
| | D2 | — | 2 | 2 | 2 | 2 | 2 | 3 | 2 | — | — |
| | D3 | 0.5 | 0.5 | 0.5 | 0.5 | 0.5 | 0.5 | 1 | 0.5 | 0.5 | — |
| Component (E) | E1 | 10 | 10 | 10 | 10 | 10 | 10 | 10 | 10 | 10 | 10 |
| Component (F) | F1 | 3 | 3 | 3 | 3 | 3 | 3 | 3 | 3 | 3 | 3 |
| | F2 | — | — | 0.5 | 0.5 | 0.5 | 0.5 | — | — | — | — |
| Component (G) | G1 | 130 | 130 | 130 | 130 | 130 | 130 | 130 | 130 | 130 | 130 |

### (Crack Evaluation)

The obtained resin composition was spin-coated on a Si substrate, and heated and dried on a hot plate at 110° C. for 180 seconds to form a resin film such that the film thickness after drying became 15 μm.

The obtained resin film was exposed to light by an i-line stepper FPA-3000iW (manufactured by Canon Inc.) using a mask. The resin film after exposure was developed with a 2.38% by mass aqueous solution of tetramethylammonium hydroxide to obtain a patterned resin film having a film thickness after development of 11.5 μm. After standing the obtained patterned resin film for 168 hours, the patterned resin film after standing was observed by a metal microscope. The case where no crack occurs in the resin film was classified as “o”, and the case where cracks occur was classified as “x”.

The results are shown in Table 2.

### (Production of Cured Products 1)

The patterned resin films obtained in the crack evaluation of Examples 1 to 8 were heated at 320° C. for 1 hour in a nitrogen atmosphere using a vertical diffusion furnace p-TF (manufactured by Koyo Thermo Systems Co., Ltd.) to obtain a patterned cured product (film thickness after curing: 7 μm).

Good patterned cured products were obtained.

### (Production of Cured Product 2)

The above-mentioned resin composition was spin-coated on a Cu plated wafer (Si wafer on which Cu plating was formed with a thickness of 10 μm) using a coating device Act8 (manufactured by Tokyo Electron Limited) such that the film thickness after drying was 11.2 μm, and dried at 120° C. for 4 minutes and 30 seconds to forma resin film.

The obtained resin film was heated at 320° C. for 1 hour in a nitrogen atmosphere using a vertical diffusion furnace p-TF to obtain a cured product (on a Cu plating), which has a film thickness after curing of about 9 μm.

### (Production of Cured Product 3)

A cured product was produced in the same manner as in Production of cured product 2, except that the Cu plated wafer was changed to a SiN layer formed wafer (Si wafer on which a SiN layer was formed with a thickness of 10 μm), and a cured product (on a SiN layer) was obtained, which has a film thickness after curing about 9 μm.

### (PCT1)

The cured product (on a Cu plated wafer) obtained in Production of cured product 2 described above was treated at 121° C. under 100 RH (Relative Humidity) % and a pressure of 2 atm for 168 hours using a PCT (Pressure Cooker Test) testing apparatus HASTEST (PC-R8D, manufactured by HIRAYAMA Manufacturing Corporation).

The cured product was taken out from the PCT testing apparatus, and a cured product after PCT (on a Cu plated wafer) was obtained.

### (PCT2)

The cured product (on a SiN wafer) obtained in Production of cured product 3 described above was treated in the same manner as PCT1 to obtain a cured product after PCT (on a SiN wafer).

### (HTS1)

The cured product (on a Cu plated wafer) obtained in the above-mentoned Production of cured product 2 was placed in a dean oven DT-41 (manufactured by Yamato Scientific Co., Ltd.), subjected to a storage treatment at a temperature of 150° C. for 168 hours, and then, taken out from the dean oven to obtain a cured product after a high temperature storage test (HTS, High Temperature Storage, Test) (on a Cu plated wafer).

### (HTS2)

The cured product (on a SiN wafer) obtained in Production of cured product 3 described above was treated in the same manner as in HTS1 to obtain a cured product after HTS (on a SiN wafer).

### (Evaluation 1 of Adhesiveness to Cu)

The epoxy resin layer at the tip of the aluminum stud was fixed on the surface of each of the cured product (on a Cu plated wafer) obtained in the above-described Production of cured product 2, the above-described cured product after PCT (on a Cu plated wafer), and the above-described cured product after HTS (on a Cu plated wafer), and the epoxy resin layer and the cured product was adhered by heating in an oven at 150° C. for 1 hour. Then, using a thin film adhesion strength measuring apparatus ROMULUS (manufactured by QUAD Group Inc.), the stud was pulled, the load at the time of peeling was measured, and the peeling mode was observed.

The case where the peeling mode was an epoxy cohesive fracture, in which no peeling was occurred between the cured product and the Cu plated wafer, was classified as “o”. The case where the peeling was occurred between the cured product and the Cu plated wafer was classified as “x”.

In the case where epoxy cohesive fracture is occurred, it is indicated that the adhesive strength between the cured product and the Cu-plated wafer is stronger than the cohesive fracture strength of the cured product.

The results are shown in Table 2. In the table, “-” indicates that no measurement was performed.

### (Evaluation 2 of Adhesiveness to Cu)

For the cured product (on a Cu plated wafer) obtained in the above-described Production of cured product 2, the above-described cured product after PCT (on a Cu plated wafer) and the above-described cured product after HTS (on a Cu plated wafer), the adhesiveness of the cured product to the Cu plated wafer was evaluated respectively, according to the cross-cut method of JIS K 5600-5-6 standard based on the following criteria. Specifically, among 10×10 grids, the number of grids of the cured product adhering to the Cu plating wafer was evaluated. The results are shown in Table 2.

“o”: The number of grids of the cured product that remains attached to the Cu-plated wafer is 100.

“x”: The number of grids of the cured product that remains attached to the Cu-plated wafer is 99 or less.

### (Evaluation 1 of Adhesiveness to SiN)

The cured product (on the SiN wafer) obtained in the above-described Production of cured product 3, the above-described cured product after PCT (on the SiN wafer) and the above-described cured product after HTS (on the SiN wafer) were evaluated, respectively, in the same manner as in the Evaluation 1 of adhesiveness to Cu except that the Cu plated wafer was changed to the SiN wafer.

The results are shown in Table 2.

### (Evaluation 2 of Adhesiveness to SiN)

The cured product (on a SiN wafer) obtained in the above-described Production of cured product 3, the above-described cured product after PCT (on a SiN wafer) and the above-described cured product after HTS (on a SiN wafer) were evaluated, respectively, in the same manner as in the Evaluation 2 of adhesiveness to Cu except that a Cu plated wafer was changed to a SiN wafer.

The results are shown in Table 2.

### (SAICAS Evaluation on Cu Plated Wafer)

For the cured product (on a Cu plated wafer) obtained in the above-described Production of cured product 2, the above-described cured product after PCT (on a Cu plated wafer), and the above-described cured product after HTS (on a Cu plated wafer), SAICAS (Surface And Interfacial Culling Analysis System) evaluation was performed, respectively, based on the following criteria, using a SAICAS EN type (manufactured by DAIPLA WINTES CO., LTD.).

Mode: constant speed mode

Measurement time: 300 seconds

Types of cutting edge: BN

Rake angle of cutting edge: 20°

Clearance angle of cutting edge: 10°

Tooth width: 1 mm

Horizontal moving speed: 3 μm/sec

Vertical moving speed: 0.1 μm/sec

The surface of the Cu plated wafer after SAICAS evaluation was observed using a microscope. The case where cohesive fracture of the cured product was observed was classified as “o”. The case where no cohesive fracture of the cured product was observed and the peeling off was occurred between the surface of the Cu plated wafer and the cured product was classified as “x”. The results are shown in Table 2. In the table, “-” indicates that no measurement was performed.

TABLE 2

| | | Ex. 1 | Ex. 2 | Ex. 3 | Ex. 4 | Ex. 5 | Ex. 6 | Ex. 7 | Ex. 8 | Comp. Ex. 1 | Comp. Ex. 2 |
|---|---|---|---|---|---|---|---|---|---|---|---|
| Crack evaluation | | ○ | ○ | ○ | ○ | ○ | ○ | ○ | ○ | x | x |
| Evaluation 1 of | Cured product | ○ | ○ | ○ | ○ | ○ | ○ | ○ | ○ | ○ | ○ |
| adhesiveness to | Cured product | x | ○ | ○ | ○ | ○ | ○ | ○ | ○ | x | x |
| Cu | after PCT | | | | | | | | | | |
| | Cured product | ○ | ○ | ○ | ○ | ○ | ○ | ○ | — | ○ | x |
| | after HTS | | | | | | | | | | |
| Evaluation 2 of | Cured product | ○ | ○ | ○ | ○ | ○ | ○ | ○ | ○ | ○ | x |
| adhesiveness to | Cured product | x | ○ | ○ | ○ | ○ | ○ | ○ | ○ | x | x |
| Cu | after PCT | | | | | | | | | | |
| | Cured product | ○ | ○ | ○ | ○ | ○ | ○ | ○ | ○ | ○ | x |
| | after HTS | | | | | | | | | | |
| Evaluation 1 of | Cured product | ○ | ○ | ○ | ○ | ○ | ○ | ○ | ○ | ○ | ○ |
| adhesiveness to | Cured product | ○ | ○ | ○ | ○ | ○ | ○ | ○ | ○ | ○ | x |
| SIN | after PCT | | | | | | | | | | |
| | Cured product | ○ | ○ | ○ | ○ | ○ | ○ | ○ | ○ | ○ | x |
| | after HTS | | | | | | | | | | |
| Evaluation 2 of | Cured product | ○ | ○ | ○ | ○ | ○ | ○ | ○ | ○ | ○ | x |
| adhesiveness to | Cured product | x | ○ | ○ | ○ | ○ | ○ | ○ | ○ | x | x |
| SIN | after PCT | | | | | | | | | | |
| | Cured product | ○ | ○ | ○ | ○ | ○ | ○ | ○ | ○ | ○ | x |
| | after HTS | | | | | | | | | | |
| SAICAS evaluation | Cured product | ○ | ○ | ○ | ○ | ○ | ○ | ○ | — | x | — |
| on Cu plated wafer | Cured product | x | ○ | ○ | ○ | ○ | ○ | ○ | — | x | — |
| | after PCT | | | | | | | | | | |

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification are incorporated herein by reference in its entirety.

1. A resin composition comprising:
the following component (A),
the following component (B), and
one or more selected from the group consisting of the following component (C) and the following component (D):
(A) polyimide, a polyimide precursor, polybenzoxazole, or a polybenzoxazole precursor
(B) one or more selected from the group consisting of a compound represented by the following formula (11), a compound represented by the following formula (21), and N-methyl-2-pyrrolidone
(C) a rust inhibitor
(D) a silane coupling agent 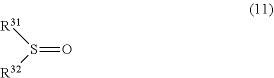
wherein in the formula (11), R³¹ and R³² are independently an alkyl group including 1 to 10 carbon atoms; 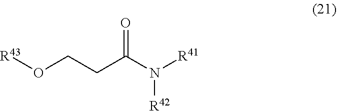
wherein in the formula (21), R⁴¹ to R⁴³ are independently an alkyl group including 1 to 10 carbon atoms.

2. The resin composition according to claim 1, wherein the component (A) is the polybenzoxazole precursor.

3. The resin composition according to claim 1, wherein the polybenzoxazole precursor is a polybenzoxazole precursor having a structural unit represented by the following formula (I): 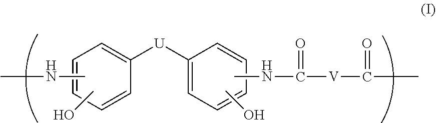
wherein in the formula (I), U is a divalent organic group, a single bond, —O— or —SO₂—, and V represents a divalent organic group.

4. The resin composition according to claim 1, wherein the component (B) is the compound represented by the formula (11).

5. The resin composition according to claim 1, wherein the component (C) is a nitrogen-containing heterocyclic compound.

6. The resin composition according to claim 1, wherein the component (D) comprises one or more selected from the group consisting of a silane coupling agent having a hydroxy group (D1) and a silane coupling agent having a urea bond (D2).

7. The resin composition according to claim 6, wherein the content of the component (D1) is 0.1 to 20 parts by mass based on 100 parts by mass of the component (A).

8. The resin composition according to claim 6, wherein the content of the component (D1) is 2.0 to 6.5 parts by mass based on 100 parts by mass of the component (A).

9. The resin composition according to claim 6, wherein the one or more selected from the group consisting of the component (C) and the component (D) are one or more selected from the group consisting of a triazole derivative, a tetrazole derivative, the component (D1), and the component (D2).

10. A resin composition according to claim 1, which is a photosensitive resin composition.

11. A method of production of a cured product comprising steps of:
applying the resin composition according to claim 1 on a substrate and drying to form a resin film, and
heat-treating the resin film.

12. A cured product obtained by curing the resin composition according to claim 1.

13. A patterned cured product obtained by curing the resin composition according to claim 10.

14. An interlayer insulating film, a cover coat layer, or a surface protective film manufactured using the cured product according to claim 12.

15. An electronic component comprising the interlayer insulating film, the cover coat layer, or the surface protective film according to claim 14.

16. An interlayer insulating film, a cover coat layer, or a surface protective film manufactured using the patterned cured product according to claim 13.

17. An electronic component comprising the interlayer insulating film, the cover coat layer, or the surface protective film according to claim 16.
